(19) United States
(12) Patent Application Publication
(10) Pub. No.: US 2026/0165085 A1
(43) Pub. Date: Jun. 11, 2026

(54) TRANSFER ROBOT AND SUBSTRATE PROCESSING APPARATUS

(71) Applicant: SEMES CO., LTD., Cheonan-si (KR)

(72) Inventors: Myung Jin LEE, Hwaseong-si (KR); Na Hyun LEE, Ansan-si (KR); Sang Oh KIM, Seoul (KR); Min Seong KIM, Hwaseong-si (KR)

(73) Assignee: SEMES CO., LTD., Cheonan-si (KR)

(21) Appl. No.: 19/416,052

(22) Filed: Dec. 11, 2025

(30) Foreign Application Priority Data
Dec. 11, 2024 (KR) 10-2024-0183824

(51) Int. Cl. H10P 72/76; B08B 3/04; H10P 72/50

(52) U.S. Cl. CPC H10P 72/7602; B08B 3/04; H10P 72/50

(57) ABSTRACT

Provided is a transfer robot for transferring a substrate. The transfer robot includes: a base; an arm which is connected to the base and is movable forward and backward with respect to the base; a hand connected to the arm; a driving unit for driving the arm; and a body which includes an electromagnet and is fixedly installed on the base, in which the hand includes: a support plate; a front guide fixedly installed at a front end of an upper surface of the support plate to support a region of a lower surface of an edge of a substrate placed on the support plate; a rear guide fixedly installed at a rear side of the upper surface of the support plate and including a rear support surface for supporting the region of the lower surface of the edge of the substrate placed on the support plate; and a movable guide unit located at the rear side of the upper surface of the support plate and movable between a first position at which the substrate is not supported and a second position capable of supporting the region of the lower surface of the substrate, the movable guide unit includes: a rail; a movable guide including a movable support surface capable of supporting the region of the lower surface of the substrate, and movable along the rail; a support rod connected to the movable guide; and a first magnetic block fixedly installed on the support rod and connectable with the electromagnet by magnetic force.

### CROSS-REFERENCE TO RELATED APPLICATION

This application claims priority to and the benefit of Korean Patent Application No. 10-2024-0183824 filed in the Korean Intellectual Property Office on Dec. 11, 2024, the entire contents of which are incorporated herein by reference.

### TECHNICAL FIELD

The present invention relates to a transfer robot and a substrate processing apparatus, and more particularly, to a transfer robot that transfers a substrate and a substrate processing apparatus including the same.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate. Since the substrate before processing before the cleaning process contains contaminants, such as particles and fumes, there is a problem of reverse contamination of a hand and the substrate when the contaminated (dirty) substrate before processing and the clean substrate after the cleaning process are transferred using the same hand. Accordingly, a method of transferring the substrate before processing and the substrate after the cleaning process using different hands is known.

However, when the substrate before processing and the substrate after processing are transferred using different hands, not only does the number of hands increase, but also the size of the transfer robot increases, and the hand that can transfer the substrate varies depending on whether the substrate has been processed or not, so there is a problem that the transfer efficiency of the substrate is reduced.

### SUMMARY OF THE INVENTION

The present invention has been made in an effort to provide a transfer robot capable of improving substrate transfer efficiency and a substrate processing apparatus including the same.

The present invention has also been made in an effort to provide a transfer robot with simplified configurations and a substrate processing apparatus including the same.

The present invention has also been made in an effort to provide a transfer robot capable of transferring a substrate before processing and a substrate after processing through one hand and preventing the substrate from being contaminated, and a substrate processing apparatus including the same.

The present invention has also been made in an effort to provide a transfer robot capable of transferring substrates at different heights using one hand without installing a separate driving unit on the hand and a substrate processing apparatus including the same.

The objectives of the present disclosure are not limited thereto and other objectives not stated herein may be clearly understood by those skilled in the art from the following description.

An exemplary embodiment of the present disclosure, a transfer robot for transferring a substrate, the transfer robot comprising: a base; an arm which is connected to the base and is movable forward and backward with respect to the base; a hand connected to the arm; a driving unit for driving the arm; and a body which includes an electromagnet and is fixedly installed on the base, wherein the hand includes: a support plate; a front guide fixedly installed at a front end of an upper surface of the support plate to support a region of a lower surface of an edge of a substrate placed on the support plate; a rear guide fixedly installed at a rear side of the upper surface of the support plate and including a rear support surface for supporting the region of the lower surface of the edge of the substrate placed on the support plate; and a movable guide unit located at the rear side of the upper surface of the support plate and movable between a first position at which the substrate is not supported and a second position capable of supporting the region of the lower surface of the substrate, the movable guide unit includes: a rail; a movable guide including a movable support surface capable of supporting the region of the lower surface of the substrate, and movable along the rail; a support rod connected to the movable guide; and a first magnetic block fixedly installed on the support rod and connectable with the electromagnet by magnetic force.

According to the exemplary embodiment of the present invention, wherein the front guide includes: a first front support part for supporting the substrate at a first height; and a second front support part for supporting the substrate at a second height different from the first height, the rear guide is provided to support the substrate at the first height, and the movable guide may be provided to support the substrate at the second height when the movable guide is in the second position.

According to the exemplary embodiment of the present invention, wherein the hand further includes a permanent magnet fixedly installed on an upper portion of the support plate, the movable guide unit further includes a second magnetic block and a third magnetic block fixedly installed on the support rod, the second magnetic block is magnetically coupled to the permanent magnet when the movable guide unit is in the first position to fix a position of the movable guide unit with respect to the support plate, and the third magnetic block may be magnetically coupled to the permanent magnet when the movable guide unit is in the second position to fix the position of the movable guide unit with respect to the support plate.

According to the exemplary embodiment of the present invention, wherein the front guide, the rear guide, the third magnetic block, the second magnetic block, and the first magnetic block may be sequentially arranged in one direction.

According to the exemplary embodiment of the present invention, wherein each of the first front support part, the second front support part, the rear support surface, and the movable support surface may be formed with a support protrusion supporting the lower surface of the substrate.

According to the exemplary embodiment of the present invention, wherein when the movable guide is in the first position, the substrate is supported by the first front support part and the rear support surface, and when the movable guide is in the second position, the substrate may be supported by the second front support part and the movable support surface.

According to the exemplary embodiment of the present invention, wherein when viewed from above, a center position of the substrate when the first front support part and the rear support surface support the substrate at the first height and a center position of the substrate when the second front support part and the movable support surface support the substrate at the second height may be provided different from each other.

According to the exemplary embodiment of the present invention, wherein the movable guide further may includes a movable guide surface that guides a lateral surface of the substrate supported by the first front support part and the rear support surface when the movable guide is in the first position.

According to the exemplary embodiment of the present invention, wherein the support plate includes: a connection part coupled to the arm; and a first finger and a second finger extending from the connection part, and the front guide is provided to each of front ends of the first finger and the second finger, and the connection part may be provided with the rear guide and the movable guide.

According to the exemplary embodiment of the present invention, wherein the front guide may be provided as an integrated body including a first front support surface provided as the first front support part and a second front support surface provided as the second front support part.

According to the exemplary embodiment of the present invention, wherein a plurality of arms is provided, and each of the plurality of arms may be provided with one or more hands coupled to be spaced apart in a vertical direction.

According to the exemplary embodiment of the present invention, further comprising: a controller, wherein the controller may changes a relative position of the movable guide unit with respect to the support plate by controlling the first magnetic block to be selectively coupled with the electromagnet by turning on/off a power applied to the electromagnet.

According to the exemplary embodiment of the present invention, wherein when the hand supports a substrate before processing, the controller switches a position of the movable guide to the first position to control the front guide and the rear guide to support the substrate before processing at the first height, and when the hand supports a substrate after processing, the controller switches the position of the movable guide to the second position may control the front guide and the movable guide to support the substrate after processing at the second height.

An exemplary embodiment of the present disclosure, an apparatus for processing a substrate, the apparatus comprising: an index module including a load port for loading and unloading a substrate; a treating module including a process chamber for processing a substrate; a controller; and the transfer robot of claim 1 for transferring the substrate between the index module and the treating module, wherein the hand further includes a permanent magnet fixedly installed on an upper portion of the support plate, the movable guide unit further includes a second magnetic block and a third magnetic block fixedly installed on the support rod, the second magnetic block is magnetically coupled to the permanent magnet when the movable guide unit is in the first position to fix a position of the movable guide unit with respect to the support plate, the third magnetic block is magnetically coupled to the permanent magnet when the movable guide unit is in the second position to fix a position of the movable guide unit with respect to the support plate, the front guide includes: a first front support part for supporting the substrate at a first height; and a second front support part for supporting the substrate at a second height different from the first height, the rear guide is provided to support the substrate at the first height, and the movable guide is provided to support the substrate at the second height when the movable guide is in the second position, and when the hand transfers a first substrate and a second substrate, the controller may changes a relative position of the movable guide with respect to the support plate to transfer the substrates in a state where the hand supports the respective substrates at different heights.

According to the exemplary embodiment of the present invention, wherein the controller may changes the relative position of the movable guide unit with respect to the support plate by controlling the first magnetic block to be selectively coupled with the electromagnet by turning on/off a power applied to the electromagnet.

According to the exemplary embodiment of the present invention, wherein the first substrate is a substrate before processing that has not been processed in the process chamber, and the second substrate is a substrate after processing that has been processed in the process chamber, and when the hand transfers the substrate before processing, the controller switches a position of the movable guide to the first position to control the front guide and the rear guide to support the substrate before processing at the first height, and when the hand transfers the substrate after processing, the controller switches the position of the movable guide to the second position may control the front guide and the movable guide to support the substrate after processing at the second height.

According to the exemplary embodiment of the present invention, wherein when viewed from above, a center position of the substrate when the first front support part and the rear support surface support the substrate before processing at the first height and a center position of the substrate when the second front support part and the movable support surface support the substrate after processing at the second height may be different from each other.

An exemplary embodiment of the present disclosure, a transfer robot for transferring a substrate, the transfer robot comprising: a base; an arm which is connected to the base and is movable forward and backward with respect to the base; a hand connected to the arm; a driving unit for driving the arm; and a body which includes an electromagnet and is fixedly installed on the base, wherein the hand includes: a support plate; a front guide fixedly installed at a front end of an upper surface of the support plate to support a region of a lower surface of an edge of a substrate placed on the support plate; a rear guide fixedly installed at a rear side of the upper surface of the support plate and including a rear support surface for supporting the region of the lower surface of the edge of the substrate placed on the support plate; a movable guide unit located at a rear side of the upper surface of the support plate and movable between a first position at which the substrate is not supported and a second position capable of supporting the region of the lower surface of the substrate; and a permanent magnet fixedly installed on an upper portion of the support plate, the front guide includes: a first front support surface for supporting the substrate at a first height; and a second front support surface for supporting the substrate at a second height different from the first height, the movable guide unit includes: a rail; a movable guide including a movable support surface capable of supporting the region of the lower surface of the substrate, and movable along the rail; a support rod connected to the movable guide; a first magnetic block installed on the support rod and connectable with the electromagnet by magnetic force; and a second magnetic block and a third magnetic block fixedly installed on the support rod, the second magnetic block is magnetically coupled to the permanent magnet when the movable guide unit is in the first position to fix a position of the movable guide unit with respect to the support plate, the third magnetic block is magnetically coupled to the permanent magnet when the movable guide unit is in the second position to fix a position of the movable guide unit with respect to the support plate, the rear guide is provided to support the substrate at the first height, and the movable guide may be provided to support the substrate at the second height when the movable guide is in the second position.

According to the exemplary embodiment of the present invention, wherein when the movable guide is in the first position, the substrate is supported by the first front support surface and the rear support surface, and when the movable guide is in the second position, the substrate is supported by the second front support surface and the movable support surface, and a center position of the substrate when the first front support surface and the rear support surface support the substrate at the first height and a center position of the substrate when the second front support surface and the movable support surface support the substrate at the second height may be different from each other.

According to the exemplary embodiment of the present invention, further comprising: a controller, the controller changes a relative position of the movable guide unit with respect to the support plate by controlling the first magnetic block to be selectively coupled with the electromagnet by turning on/off a power applied to the electromagnet, and when the hand supports a substrate before processing, the controller switches a position of the movable guide to the first position to control the front guide and the rear guide to support the substrate before processing at the first height, and when the hand supports a substrate after processing, the controller switches the position of the movable guide to the second position may control the front guide and the movable guide to support the substrate after processing at the second height.

According to the exemplary embodiment of the present invention, it is possible to improve substrate transfer efficiency.

Further, according to the exemplary embodiment of the present invention, it is possible to simplify the configuration of the transfer robot.

Further, according to the exemplary embodiment of the present invention, it is possible to transfer a substrate before processing and a substrate after processing through one hand and prevent the substrate from being contaminated.

Further, according to the exemplary embodiment of the present invention, it is possible to transfer substrates at different heights using one hand without installing a separate driving unit on the hand.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a perspective view illustrating a first transfer robot according to an exemplary embodiment of the present invention.

FIG. 3 is a perspective view illustrating a hand of FIG. 2 according to an exemplary embodiment of the present invention.

FIG. 4 is a diagram schematically illustrating the configuration of a body and a movable guide unit of FIG. 3.

FIG. 5 is a side view schematically illustrating a state where the hand of FIG. 3 supports a substrate at a first height.

FIG. 6 is a side view schematically illustrating a state where the hand of FIG. 3 supports a substrate at a second height.

FIG. 7 is a top plan view schematically illustrating a state where the hand of FIG. 3 supports a substrate at the first height.

FIG. 8 is a top plan view schematically illustrating a state where the hand of FIG. 3 supports a substrate at the second height.

FIG. 9 is a side view schematically illustrating the configuration of the first transfer robot of FIG. 2.

FIG. 10 is a flowchart illustrating a method of processing a substrate using the above-described substrate processing apparatus.

FIG. 11 is a diagram illustrating a state where the movable guide of FIG. 3 is located in a first position.

FIG. 12 is a diagram illustrating a state in which the hand of FIG. 3 transfers a substrate before processing.

FIGS. 13 to 15 are diagrams illustrating a process in which the movable guide of FIG. 3 is switched from the first position to a second position.

FIG. 16 is a diagram illustrating a process in which the hand of FIG. 3 transfers a substrate after processing.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on a process of liquid-treating a substrate W by supplying a liquid, such as a cleaning liquid, onto a substrate W as an example. However, the present exemplary embodiment is not limited to the cleaning process, and may be applied to various processes of processing the substrate W using a liquid, such as an etching process, an ashing process, or a developing process.

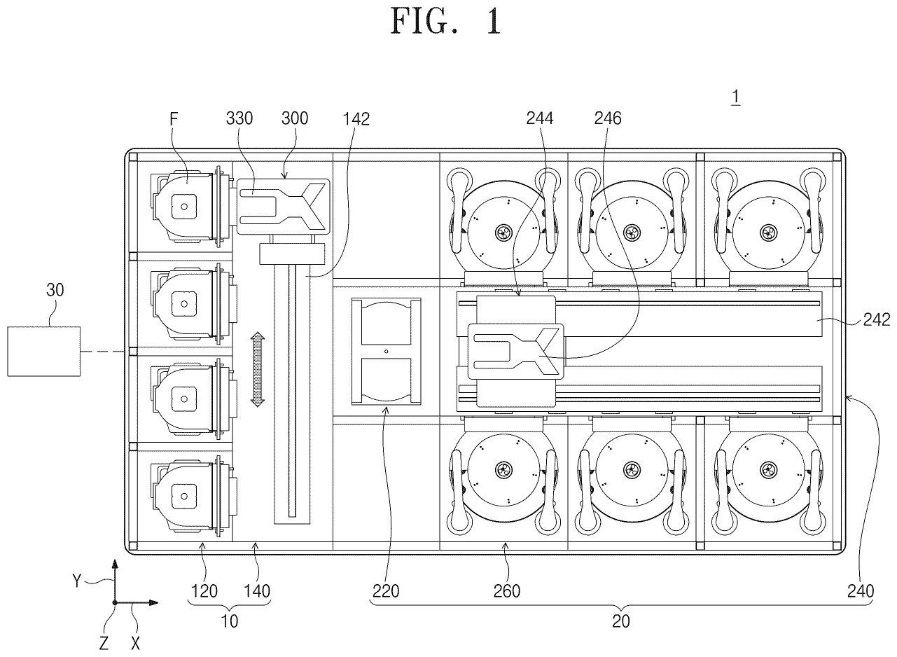

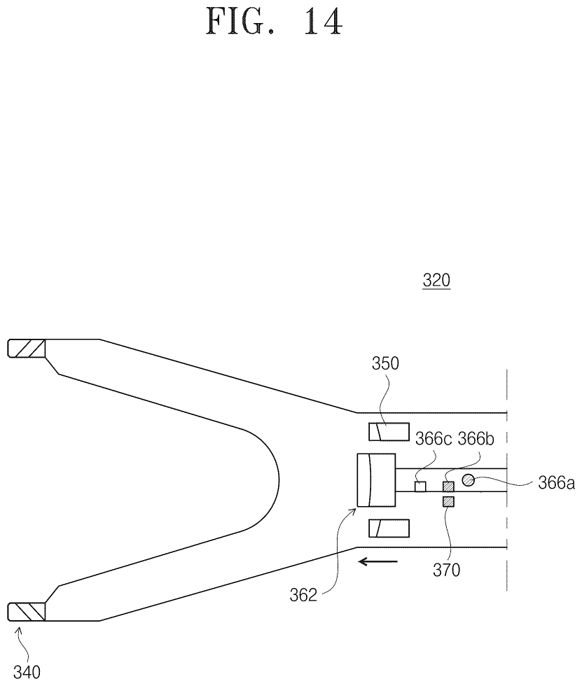

Hereinafter, an exemplary embodiment of the present invention will be described in detail with reference to FIGS. 1 to 16. A substrate processing apparatus 1 according to an exemplary embodiment of the present invention may perform a cleaning process including a drying process of drying a substrate W using a process fluid.

FIG. 1 is a diagram schematically illustrating a substrate processing apparatus according to an exemplary embodiment of the present invention. Referring to FIG. 1, a substrate processing apparatus 1 includes an index module 10, a treating module 20, and a controller 30. According to an example, the index module 10 and the treating module 20 are disposed along one direction. Hereinafter, a direction in which the index module 10 and the treating module 20 are arranged is defined as a first direction X. When viewed from the top, a direction perpendicular to the first direction X is defined as a second direction Y, and a direction perpendicular to a plane including both the first direction X and the second direction Y is defined as a third direction Z.

The index module 10 transfers a substrate W from a container F in which the substrate W is accommodated to the treating module 20 processing the substrate W. The index module 10 accommodates the substrate W completely processed in the treating module 20 in the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction Y. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and a first transfer robot 300 are provided inside the index frame 140. The index rail 142 is provided in the index frame 140 along the second direction Y in its longitudinal direction. The first transfer robot 300 may transfer the substrate W.

The first transfer robot 300 may transfer the substrate W between the index module 10 and the treating module 20. The first transfer robot 300 may transfer the substrate W between the load port 120 and a buffer chamber 220 to be described below. The first transfer robot 300 may be called as an index robot. A detailed configuration of the first transfer robot 300 will be described later.

The first transfer robot 300 includes a plurality of hands 320. The substrate W is seated on the hand 320. The first transfer robot 300 may be provided to be movable on the index rail 142 along the second direction Y. Accordingly, the hand 320 may be moved forward and backward along the index rail 142. Also, the first transfer robot 300 may be provided to be rotatable with respect to the third direction Z as an axis. Also, the first transfer robot 300 may be provided to be movable vertically along the third direction Z. The first transfer robot 300 will be described later.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform a substrate processing method described below. For example, the controller 30 may control the configurations provided to the first transfer robot 300, a second transfer robot 244, and a process chamber 260 to be described below to perform a substrate processing method described below.

The treating module 20 includes a buffer chamber 220, a transfer frame 240, and a process chamber 260. The buffer chamber 220 provides a space in which the substrate W loaded into the treating module 20 and the substrate W unloaded from the treating module 20 stay temporarily. The transfer frame 240 provides a transfer space for transferring the substrate W between the buffer chamber 220 and the process chamber 260.

The buffer chamber 220 may be disposed between the index frame 140 and the transfer chamber 240. The buffer chamber 220 may be located at one end of the transfer frame 240. A slot (not illustrated) in which the substrate W is placed is provided in the buffer chamber 220. A plurality of slots (not illustrated) is provided. A plurality of slots (not illustrated) may be disposed to be spaced apart from each other along the third direction Z. A front face and a rear face of the buffer chamber 220 are opened. The front face is a face facing the index module 10, and the rear face is a face facing the transfer frame 240. The first transfer robot 1 may approach the buffer chamber 220 through the front face, and the second transfer robot 244 may approach the buffer chamber 220 through the rear face.

A longitudinal direction of the transfer frame 240 may be provided along the first direction X. The process chambers 260 may be disposed on opposite sides of the transfer frame 240. The process chamber 260 may be disposed on a side portion of the transfer frame 240. The transfer frame 240 and the process chamber 260 may be disposed along the second direction Y.

According to the example, the process chambers 260 are disposed on opposite sides of the transfer frame 240. At one side of the transfer frame 240, the process chambers 260 may be provided in an array of A×B (each of A and B is 1 or a natural number larger than 1) in the first direction X and the third direction Z. Herein, A is the number of process chambers 260 provided in a row along the first direction X, and B is the number of process chambers 260 provided in a row along the third direction Z. For example, when six process chambers 260 are provided at one side of the transfer frame 240, the process chambers 260 may be arranged in a 3×2 array. The number of process chambers 260 may increase or decrease. Unlike the above description, the process chambers 260 may be provided as a single layer on one side and opposite sides of the transfer frame 240.

The transfer frame 240 includes a guide rail 242 and a second transfer robot 244. The guide rail 242 is provided within the transfer frame 240 in the first direction X in a longitudinal direction thereof. The second transfer robot 244 may be provided on the guide rail to be able to move linearly in the first direction X. The second transfer robot 244 transfers the substrate W between the buffer chamber 220 and the process chamber 260.

The process chamber 260 may process the substrate W. The process chamber 260 may be a chamber for performing a cleaning process for removing process by-products or the like attached to the substrate W. The process chamber 260 may be provided as, for example, a liquid treating chamber 400 to perform a liquid treatment process of liquid-treating the substrate W by supplying a liquid onto the substrate W. Hereinafter, the present invention will be described based on the case where the process chamber 260 is the liquid treating chamber 400 as an example. The liquid treating chamber 400 may process the substrate W by supplying a chemical, a rinse liquid, and/or an organic solvent onto the substrate W. The processing of the substrate W performed in the liquid treating chamber 400 may include a spin drying treatment in which the liquid remaining on the substrate W is removed by rotating the substrate W.

The process chamber 260 may have different structures depending on the type of process for processing the substrate W. Alternatively, each of the process chambers 260 may have the same structure.

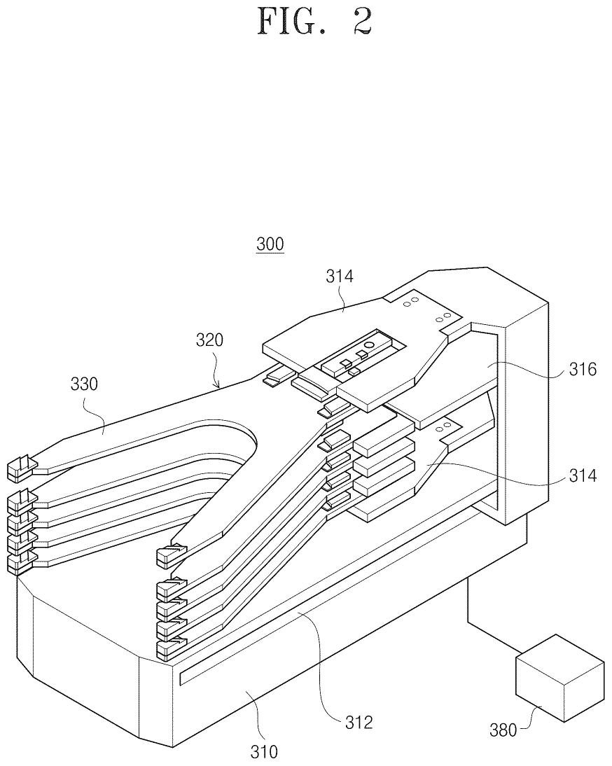

FIG. 2 is a perspective view illustrating the first transfer robot according to a first exemplary embodiment of the present invention. Referring to FIGS. 1 and 2, the first transfer robot 300 includes a base 310, an arm 314, a body 316, a hand 320, and a driving unit 380.

The base 310 supports the arm 314 and the hand 320 connected to the arm 314. The arm 314 is connected with the base 310. An end of the arm 314 is connected to the hand 320.

The base 310 is installed to be movable along the index rail 142. The base 310 may be axially rotated with respect to a support shaft (not illustrated) in the third direction Z. The base 310 may have a generally rectangular parallelepiped shape. The base 310 is provided such that a longitudinal direction thereof is directed in a horizontal direction. A guide 312 is provided on the base 310. The guide 312 guides the moving direction of the arm 314 so that the arm 314 and the hand 320 coupled to the arm 314 may move linearly along the longitudinal direction of the base 310. A plurality of guides 312 may be provided. The arm 314 is provided to be able to move forward and backward with respect to the base 310 by the driving unit 380. According to an example, the same number of guides 312 as the arm 314 may be provided. Each of the guides 312 may be provided such that a longitudinal direction thereof is parallel to the base 310.

The arm 314 and the hand 320 coupled to the arm 314 may be stacked on the base 310 to be spaced apart from each other in a vertical direction and may be provided in plural. A plurality of arms 314 may linearly move independently of each other by the driving unit 380.

In the following exemplary embodiment, it will be illustrated and described that the first transfer robot 300 includes two arms 314 and five hands 320, including the arm 314 coupled with one hand 320 and the arm 314 coupled with four hands 320, but the number of arms 314 and hands 320 may be freely changed according to the process efficiency of the substrate processing apparatus 1.

The body 316 is connected to the base 310 and fixedly installed on the upper portion of the base 310. The body 316 includes an electromagnet 316a.

The electromagnet 316a may be fixedly installed on the body 316 and magnetically connected to a first magnetic block 366a provided on a support rod 366 of the hand 320 to be described later. A plurality of electromagnets 316a may be provided to correspond to the number of support rods 366. Although not illustrated, a configuration of applying power to the electromagnet 316a may be included. For example, the electromagnet 316a may generate magnetic force by applying power to the driving unit 380. Details of the electromagnet 316a will be described later.

The hand 320 supports the substrate W. The hand 320 is coupled to the arm 314.

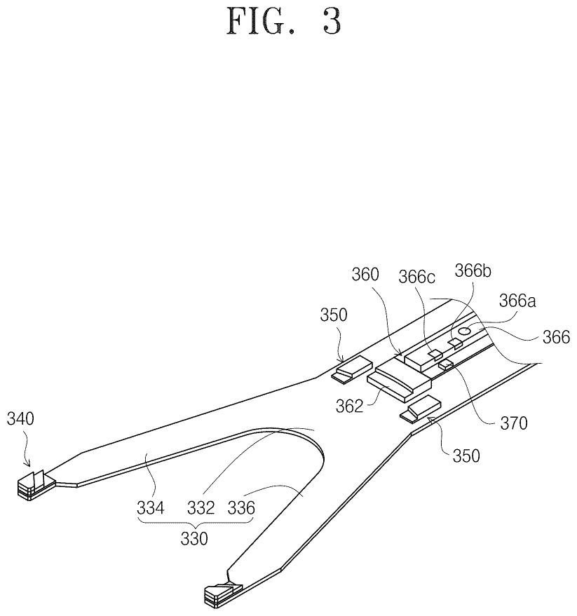

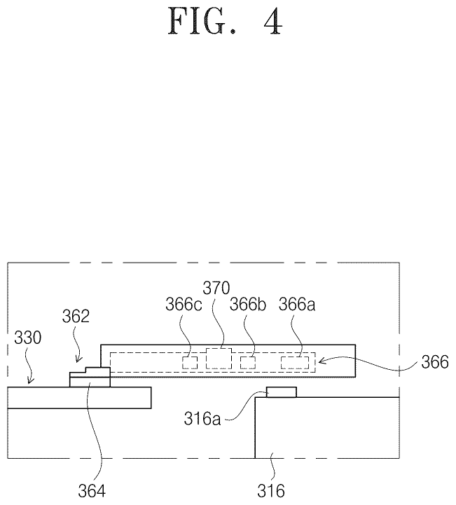

FIG. 3 is a perspective view illustrating the hand of FIG. 2 according to the exemplary embodiment of the present invention, and FIG. 4 is a diagram schematically illustrating the configurations of the body and a movable guide unit of FIG. 3.

Hereinafter, the hand 320 according to the exemplary embodiment of the present invention will be described in detail with reference to FIGS. 3 to 4 in addition to FIG. 2.

The hand 320 includes a support plate 330, a front guide 340, a rear guide 350, a movable guide unit 360, and a permanent magnet 370.

The support plate 330 is coupled to the arm 314. The support plate 330 includes a connection part 332, a first finger 334, and a second finger 336.

The first finger 334 and the second finger 336 have a rod shape, are spaced apart from each other and positioned to face each other, and are provided to extend in the same direction from the connection part 332. Opposite sides of a front end of the connection part 332 are connected to the first fingerer 334 and the second fingerer 336, respectively, and a base end of the connection part 332 is connected to the base plate 314. The base end of the connection part 332 may be coupled to the arm 314.

The front guide 340 may support a region of a lower surface of a front edge of the substrate W placed on the support plate 330 and may simultaneously guide a lateral surface of the substrate W to restrict movement of the lateral surface of the substrate W. The front guide 340 may support the substrate W at a first height h1 and a second height h2.

The front guides 340 may be provided at front ends of the first finger 334 and the second finger of the support plate 330, respectively. The front guide 340 may be installed on upper surfaces of the first finger 334 and the second finger 336. The front guide 340 may be fixedly installed at a front end of the upper surface of the support plate 330. The substrate W may be mounted on the front guide 340.

The front guide 340 includes a first front support part supporting the substrate W at the first height h1 and a second front support part supporting the substrate W at the second height h2. The first height h1 and the second height h2 may be different from each other.

The rear guide 350 may support a region of a lower surface of a rear edge of the substrate W placed on the support plate 330 and simultaneously, may guide the lateral surface of the substrate W to restrict the lateral movement of the substrate W. The rear guide 350 may support the substrate W at the first height h1.

The rear guide 350 may be provided on the connection portion 332 of the support plate 330. The rear guide 350 may be fixedly installed on the upper surface of the connection part 332. The substrate W may be mounted on the rear guide 350. A plurality of rear guides 350 may be provided. For example, two rear guides 350 may be provided on the connection part 332 to support the region of the lower surface of the edge of the substrate W seated and supported on the support plate 330, as illustrated in FIG. 3.

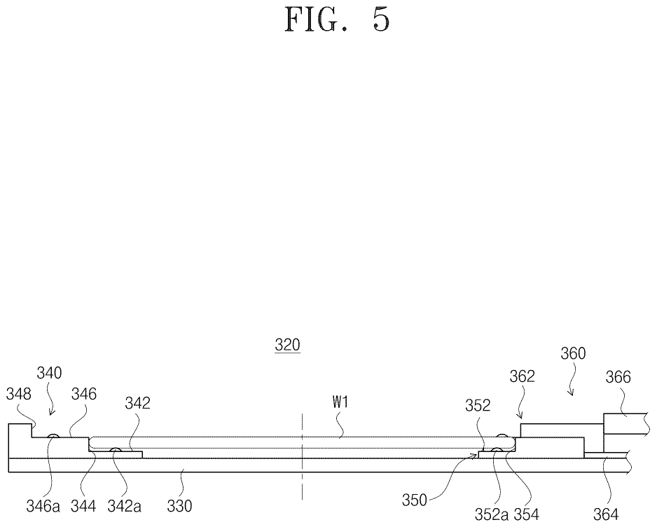

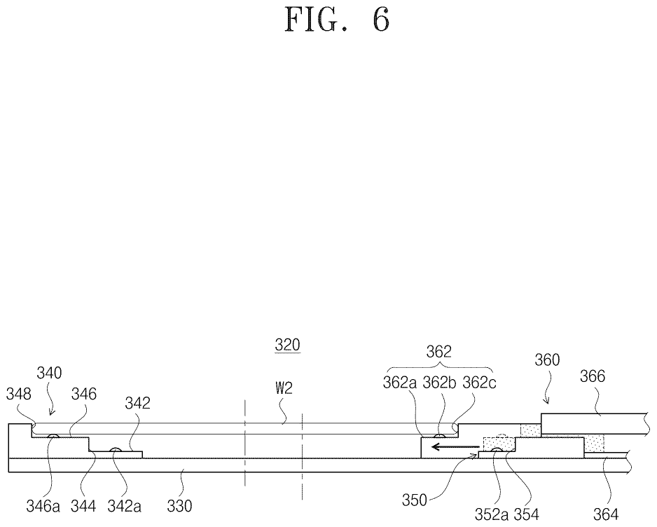

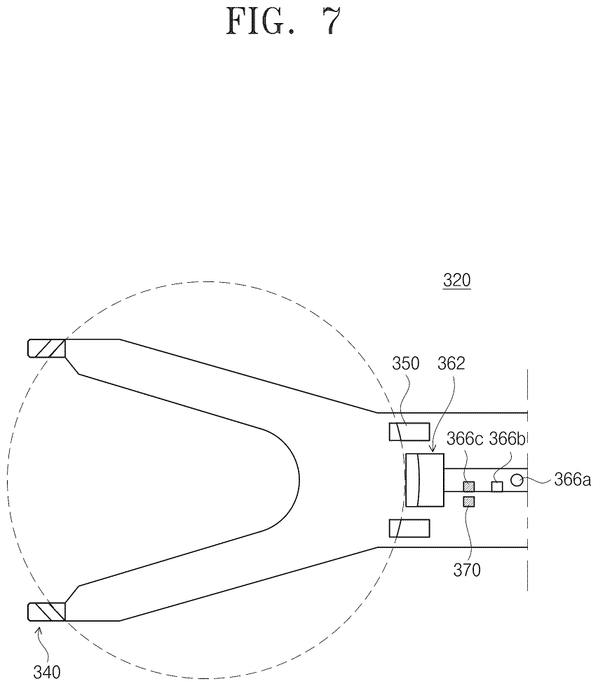

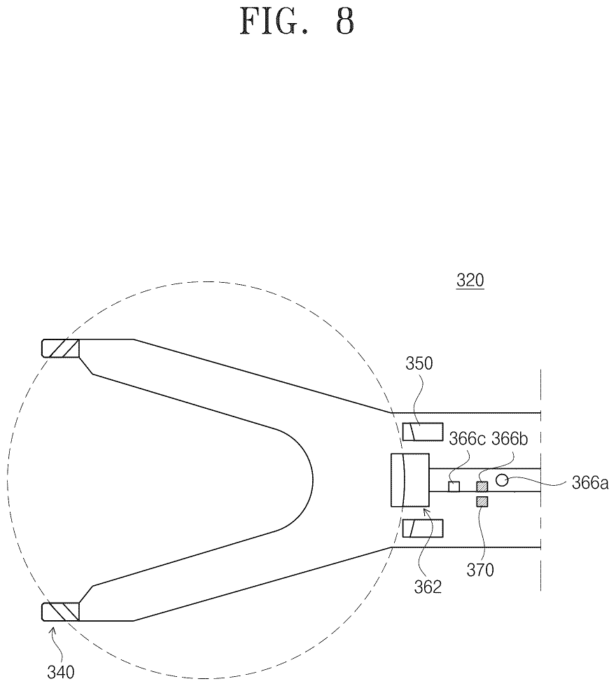

FIG. 5 is a side view schematically illustrating a state where the hand of FIG. 3 supports a substrate at a first height, and FIG. 6 is a side view schematically illustrating a state where the hand of FIG. 3 supports a substrate at a second height. Further, FIG. 7 is a top plan view schematically illustrating a state where the hand of FIG. 3 supports a substrate at the first height, and FIG. 8 is a top plan view schematically illustrating a state where the hand of FIG. 3 supports a substrate at the second height.

Hereinafter, detailed configurations of the front guide 340, the rear guide 350, and the movable guide unit 360 will be described with reference to FIGS. 3 to 8.

The front guide 340 may include a first front support surface 342, a first front guide surface 344, a second front support surface 346, and a second front guide surface 348.

In the present exemplary embodiment, the first front support surface 342 is illustrated and described as a first front support part supporting the substrate W at the first height h1, and the second front support surface 346 is illustrated and described as a second front support part supporting the substrate W at the second height h2. The front guide 340 may be provided as an integrated body including the first front support surface 342 and the second front support surface 346. The body of the front guide 340 may be stepped so that the first front support surface 342 and the second front support surface 346 having different heights are provided.

A support protrusion 342a for supporting the lower surface of the substrate W when the substrate W is placed on the first front support surface 342 may be formed on the first front support surface 342.

The first front guide surface 344 may be provided adjacent to the first front support surface 342. The first front guide surface 344 may be provided perpendicular to the first front support surface 342. The first front guide surface 344 may face the end of the substrate W in a state in which the lower surface of the substrate W is supported by the first front support surface 342. When the first front support surface 342 supports the substrate W, the first front guide surface 344 may guide the lateral surface of the substrate W to restrict the lateral movement of the substrate W.

A support protrusion 346a for supporting the lower surface of the substrate W when the substrate W is placed on the second front support surface 346 may be formed on the second front support surface 346.

The second front guide surface 348 may be provided adjacent to the second front support surface 346. The second front guide surface 348 may be provided perpendicular to the second front support surface 346. The second front guide surface 348 may face the end of the substrate W in a state in which the lower surface of the substrate W is supported by the second front support surface 346. When the second front support surface 346 supports the substrate W, the second front guide surface 348 may guide the lateral surface of the substrate W to restrict the lateral movement of the substrate W.

The rear guide 350 may include a rear support surface 352 and a rear guide surface 354.

The substrate W may be seated on the rear support surface 352. A support protrusion 352a for supporting the lower surface of the substrate W when the substrate W is placed on the rear support surface 352 may be formed on the rear support surface 352.

The rear guide surface 354 may be provided adjacent to the rear support surface 352. The rear guide surface 354 may be provided perpendicular to the rear support surface 352. The rear guide surface 354 may face the end of the substrate W in a state in which the lower surface of the substrate W is supported by the rear support surface 352. When the rear support surface 352 supports the substrate W, the rear guide surface 354 may guide the lateral surface of the substrate W to restrict the lateral movement of the substrate W.

The movable guide unit 360 may support the region of the lower surface of the rear edge of the substrate W placed on the hand 320 and simultaneously guide the lateral surface of the substrate W to restrict the lateral movement of the substrate W.

The movable guide unit 360 includes a movable guide 362, a rail 364, and a support rod 366.

The movable guide 362 may be provided on the connection part 332 of the support plate 330. The movable guide 362 is provided to be horizontally movable on the connection part 332 of the support plate 330 by the support rod 366. The movable guide 362 may be provided to be horizontally movable on a rail 364. The movement direction of the movable guide 362 is a direction parallel to the forward and backward movement of the arm 314. The movable guide 362 may be located at a rear end of the upper surface of the support plate 330. The movable guide 362 may support the substrate W at the second height h2.

The movable guide 362 may include a movable support surface 362a and a movable guide surface 362c. The substrate W may be seated on the movable support surface 362a. A support protrusion 362b that supports the lower surface of the substrate W when the substrate W is placed on the movable support surface 362a may be formed on the movable support surface 362a.

The movable guide surface 362c may be provided adjacent to the movable support surface 362a. The movable guide surface 362c may be provided perpendicular to the movable support surface 362a.

The movable guide surface 362c may face the end of the substrate W in a state in which the lower surface of the substrate W is supported by the movable support surface 362a. When the movable support surface 362a supports the substrate W, the movable guide surface 362c may guide the lateral surface of the substrate W to restrict the lateral movement of the substrate W.

The movable guide 362 may slide along the rail 364. The movable guide 362 may move between a first position P1 at which the movable guide 362 does not support the substrate W and a second position P2 at which the movable guide 362 supports the substrate W at the first height h1. The first position P1 and the second position P2 may indicate specific positions on the support plate 330. As illustrated in FIG. 4, the first position P1 may refer to a position closer to a base end of the support plate 330 than the second position P2. In other words, the second position P2 may refer to a position closer to the front guide 340 than the first position P1.

When the movable guide 362 is in the second position P2, the movable guide 362 may support the substrate W at the second height h2.

The support rod 366 is coupled to the movable guide 362, and move the movable guide 362 together with the hand 320, or move the movable guide 362 relative to the hand 320. The support rod 366 may be provided in a rod shape, and may extend in a direction parallel to the forward and backward direction of the hand 320. The support rod 366 may be installed in parallel with the arm 314. The support rod 366 may include a first magnetic block 366a, a second magnetic block 366b, and a third magnetic block 366c.

The first magnetic block 366a, the second magnetic block 366b, and the third magnetic block 366c may be formed of a magnetic material. Each of the first magnetic block 366a, the second magnetic block 366b, and the third magnetic block 366c may be installed on the support rod 366. As illustrated in FIG. 4, the front guide 340, the rear guide 350, the third magnetic block 366c, the second magnetic block 366b, and the first magnetic block 366a may be sequentially arranged in one direction. A direction in which the front guide 340, the rear guide 350, the third magnetic block 366c, the second magnetic block 366b, and the first magnetic block 366a are arranged may be a direction parallel to the forward and backward direction of the hand 320.

The first magnetic block 366a may be magnetically connected to the electromagnet 316a when power is supplied to the electromagnet 316a fixedly installed in the body 316. The first magnetic block 366a may be magnetically connected to the electromagnet 316a when the electromagnet 316a fixedly installed in the body 316a is turned on and a current flows in the electromagnet 316a. The first magnetic block 366a may be disposed at a position facing the electromagnet 316a when first magnetic block 366a is magnetically connected to the electromagnet 316a.

When the first magnetic block 366a is magnetically connected to the electromagnet 316a, the movable guide unit 360 may be fixed to the base 310 by the body 316. When the first magnetic block 366a is magnetically connected to the electromagnet 316a, the position of the movable guide unit 360 may be fixed with respect to the base 310 when the support plate 330 moves forward and backward with respect to the base 314 according to the movement forward and backward of the arm 314. Accordingly, when the first magnetic block 366a is magnetically connected to the electromagnet 316a, the movable guide unit 360 may move relative to the support plate 330 as the support plate 330 moves. In other words, the relative position between the movable guide unit 360 and the support plate 330 may be changed depending on whether magnetic force is applied between the first magnetic block 366a and the electromagnet 316a.

The second magnetic block 366b and the third magnetic block 366c may be magnetically connected to the permanent magnet 370 to be described later. The second magnetic block 366b and the third magnetic block 366c may be magnetically connected to a permanent magnet 370 to be described later, according to a relative position between the movable guide unit 360 and the support plate 330. The second magnetic block 366b and the third magnetic block 366c may be magnetically coupled to the permanent magnet 370 to fix a relative position between the movable guide unit 360 and the support plate 330.

The permanent magnet 370 may be magnetically connected to the second magnetic block 366b and the third magnetic block 366c described above to fix a relative position between the movable guide unit 360 and the support plate 330. The permanent magnet 370 is installed at a position facing the support rod 366. The permanent magnet 370 is installed at a position facing the second magnetic block 366b and the third magnetic block 366c. The permanent magnet 370 may be fixedly installed on the hand 320 or the arm 314. For example, as illustrated in FIG. 4, the permanent magnet 370 may be fixedly installed on the arm 314.

Even when the second magnetic block 366b or the third magnetic block 366c is magnetically coupled to the permanent magnet 370, when power is applied to the electromagnet 316a, a position of the movable guide unit 360 may be fixed with respect to the base 310. In other words, the magnetic force between the first magnetic block 366a and the electromagnet 316a may be provided to be stronger than the magnetic force between the second magnetic block 366b or the third magnetic block 366c and the permanent magnet 370. Therefore, a relative position between the movable guide unit 360 and the support plate 330 to the first position P1 or the second position P2 may be fixed by turning off the power applied to the electromagnet 316a in a state in which the second magnetic block 366b or the third magnetic block 366c and the permanent magnet 370 are magnetically coupled to each other.

Alternatively, the relative position between the movable guide unit 360 and the support plate 330 may be changed so that the permanent magnet 370 may be switched between the state of being magnetically coupled to the second magnetic block 366b and the state of being magnetically coupled to the third magnetic block 366c by moving the arm 314 and the support plate 330 coupled to the arm 314 forwardly and backwardly while the power applied to the electromagnet 316a is turned on.

As illustrated in FIGS. 5 and 7, when the movable guide 362 is in the first position P1, a first substrate W1 is seated on the first front support surface 342 and the rear support surface 352. That is, when the movable guide 362 is in the first position P1, both the first front support surface 342 and the rear support surface 352 support the first substrate W1. The lateral movement of the first substrate W1 may be restricted by the first front guide surface 344 and the rear guide surface 354. The first substrate W1 may be positioned at the first height h1 with respect to the support plate 330.

As illustrated in FIG. 7, when the movable guide 362 is in the first position P1 on the support plate 330, the third magnetic block 366c of the support rod 366 may be magnetically coupled to the permanent magnet 370. The third magnetic block 366c may be magnetically coupled to the permanent magnet 370 to fix a relative position between the movable guide unit 360 and the support plate 330.

As illustrated in FIGS. 6 and 8, when the movable guide 362 is in the second position P2, the second substrate W2 is seated on the second front support surface 346 and the movable support surface 362a. That is, when the movable guide 362 is in the second position P2, both the second front support surface 346 and the movable support surface 362a support the second substrate W2. The lateral movement of the second substrate W2 may be restricted by the second front guide surface 348 and the movable guide surface 362c. The second substrate W2 may be located at the second height h2 with respect to the support plate 330.

As illustrated in FIG. 8, when the movable guide 362 is in the second position P2 on the support plate 330, the second magnetic block 366b of the support rod 366 may be magnetically coupled to the permanent magnet 370. The second magnetic block 366b may be magnetically coupled to the permanent magnet 370 to fix a relative position between the movable guide unit 360 and the support plate 330.

As illustrated in FIGS. 7 and 8, when viewed from above, the center position of the first substrate W1 when the front guide 340 and the rear guide 350 support the first substrate W1 at the first height h1 and the center position of the second substrate W2 when the front guide 340 and the movable guide 362 support the second substrate W2 at the second height h2 may be different from each other.

According to the above exemplary embodiment, the first substrate W1 supported by the hand 320 in the first position P1 and the second substrate W2 supported by the hand 320 in the second position P2 may be substrates of different states. For example, one of the first substrate W1 and the second substrate W2 may be a substrate that has not been processed in the process chamber 260, and the other may be a substrate that has been processed in the process chamber 260. Hereinafter, for convenience of description, it will be described that the first substrate W1 is a substrate before processing, and the second substrate W2 is a substrate after processing.

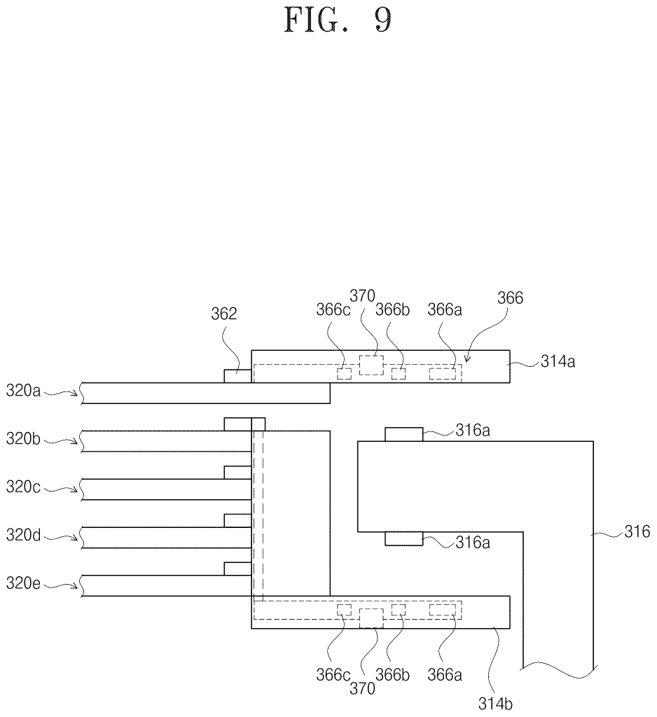

FIG. 9 is a side view schematically illustrating the configuration of the first transfer robot of FIG. 2. As illustrated in FIGS. 2 and 9, the first arm 314a may be coupled to one hand 320a, and the second arm 314b may be coupled to a plurality of hands 320b, 320c, 320d, and 320e. The plurality of hands 320b, 320c, 320d, and 320e coupled to the second arm 314b may be stacked to be spaced apart from each other in the vertical direction. Each of the arms 314a and 314b may be driven simultaneously or independently.

Each of the hands 320b, 320c, 320d, and 320e includes the movable guide 362. The movable guides 362 provided to the hands 320b, 320c, 320d, and 320e are coupled to one support rod 366, and as described above, the movable guides 362 may move together with the second arm 314b as the first magnetic block 366a, the second magnetic block 366b, and the third magnetic block 366c of the support rod 366 magnetically interact with the electromagnet 316a or the permanent magnet 370, or may be fixed in position with respect to the base 310 to move relative to the second arm 314b as the support plate 330 is moved.

As such, by the same manner as the description for the first arm 314a described in FIGS. 3 to 8, as the movable guide 362 provided to each of the hands 320b, 320c, 320d, and 320e is switched between the first position P1 and the second position P2, the hands 320b, 320c, 320d, and 320e may support and transfer the substrate W using different support surfaces at different heights h1 and h2.

Hereinafter, an exemplary embodiment of a method of processing a substrate using the substrate processing apparatus of FIG. 1 will be described. The substrate processing method described below may be performed by the substrate processing apparatus 1 including the index module 10, the buffer chamber 220, the process chamber 260, the first transfer robot 300, and the second transfer robot 244. In addition, the controller 30 may control the configurations of the substrate processing apparatus 1 to perform the substrate processing method described below.

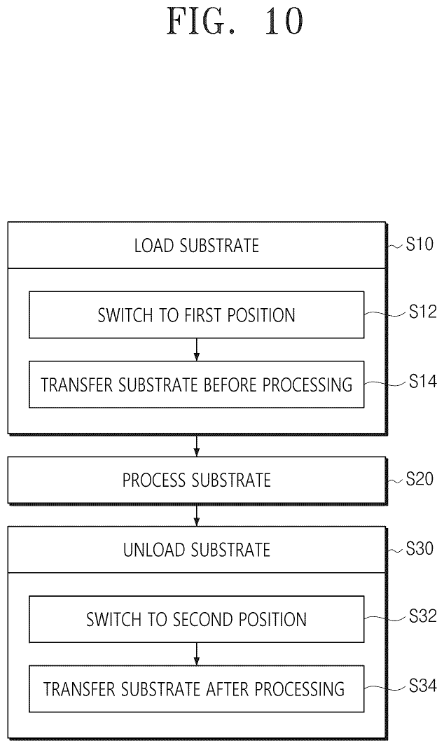

FIG. 10 is a flowchart illustrating a method of processing a substrate using the above-described substrate processing apparatus.

Referring to FIG. 10, the substrate processing method of the present invention includes a substrate loading operation S10, a substrate processing operation S20, and a substrate unloading operation S30.

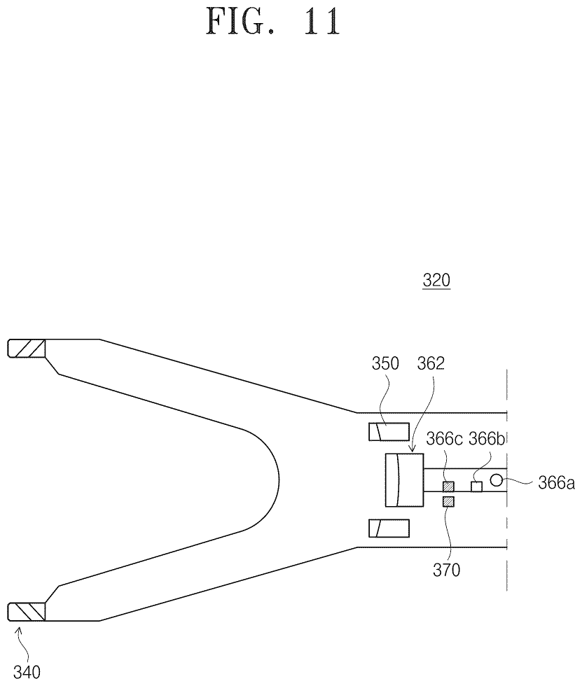

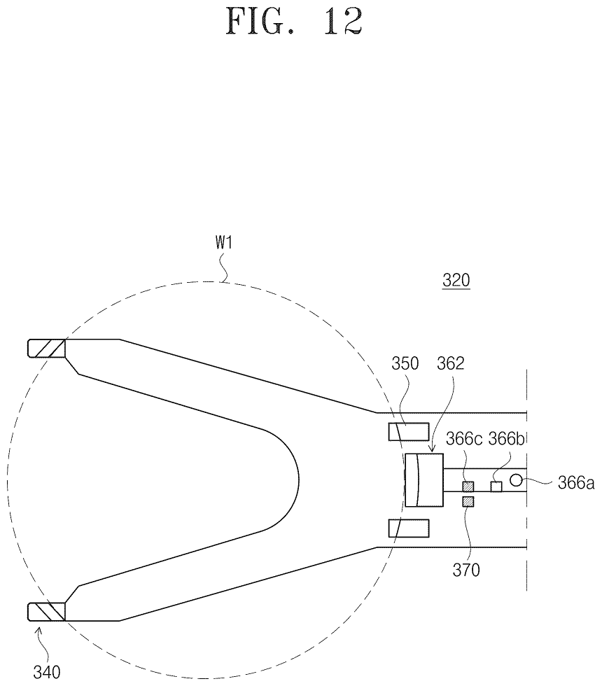

The substrate loading operation S10 in will be described with reference to FIGS. 5, 11, and 12. FIG. 11 is a diagram illustrating a state where the movable guide of FIG. 3 is located in a first position, and FIG. 12 is a diagram illustrating a state in which the hand of FIG. 3 transfers a substrate before processing.

In the substrate loading operation S10, the first transfer robot 300 provided as the index robot transfers the substrate W1 before processing from the container F in which the substrate W is accommodated to the treating module 20 that processes the substrate W. In this case, the movable guide 362 of the hand 320 provided to the first transfer robot 300 is switched to the first position P1 (S12). When the movable guide 362 is in the first position P1 on the support plate 330, the third magnetic block 366c of the support rod 366 may be magnetically coupled to the permanent magnet 370. The third magnetic block 366c may be magnetically coupled to the permanent magnet 370 to fix a relative position between the movable guide unit 360 and the support plate 330. The substrate W1 before processing is transferred to the treating module 20 in a state of being seated on the first front support surface 342 and the rear support surface 352 (S14). The substrate W1 before processing may be transferred to the buffer chamber 220 by the first transfer robot 300.

Thereafter, the substrate W1 before processing is transferred from the buffer chamber 220 to the process chamber 260 by the second transfer robot 244, and the substrate processing operation S20 is performed. In the substrate processing operation S20, the substrate W1 before processing is processed in the process chamber 260. When the process chamber 260 is a liquid treating chamber performing a cleaning process for removing process by-products and the like attached to the substrate W, the substrate W1 before processing transferred to the process chamber 260 may be cleaned by the liquid treating chamber.

The substrate processing operation S20 is terminated, and the substrate unloading operation S30 is performed. The substrate W2 after processing is transferred from the process chamber 260 to the buffer chamber 220 by the second transfer robot 244, and is transferred from the buffer chamber 220 to the index module 10 by the first transfer robot 300. In this case, the movable guide 362 of the hand 320 provided to the first transfer robot 300 is switched to the second position P1 (S32). That is, the movable guide unit 360 may be switched from a state in which the third magnetic block 366c of the support rod 366 is magnetically coupled to the permanent magnet 370 to a state in which the second magnetic block 366b is magnetically coupled to the permanent magnet 370.

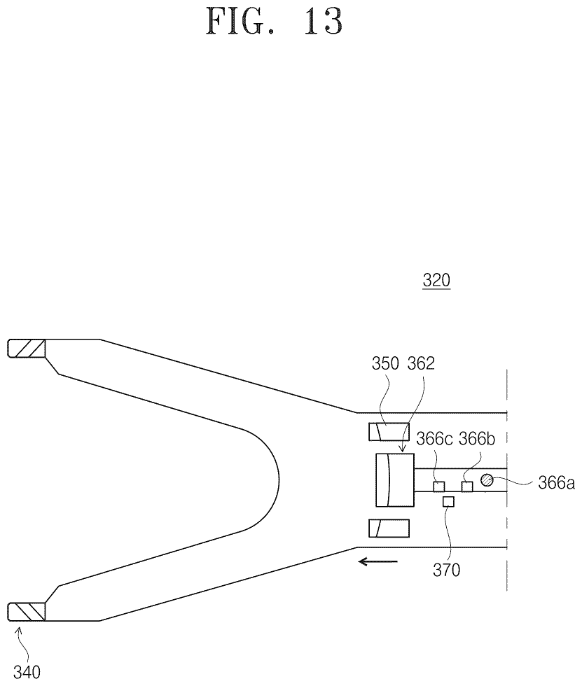

FIGS. 13 to 15 are diagrams illustrating a process in which the movable guide of FIG. 3 is switched from the first position to the second position. A second position switch operation S32 will be described with reference to FIGS. 13 to 15.

Power is applied to the electromagnet 316a of the body 316, so that the first magnetic block 366a of the movable guide unit 360 and the electromagnet 316a are magnetically coupled to each other in a forward and backward motion process of the arm 314 and the support plate 330. Since the magnetic force between the first magnetic block 366a and the electromagnet 316a is stronger than the magnetic force between the third magnetic block 366c and the permanent magnet 370, as the arm 314 and the support plate 330 retreat, the permanent magnet 370 fixed to the arm relatively moves from a position opposite to the third magnetic block 366c to a position opposite to the second magnetic block 366b.

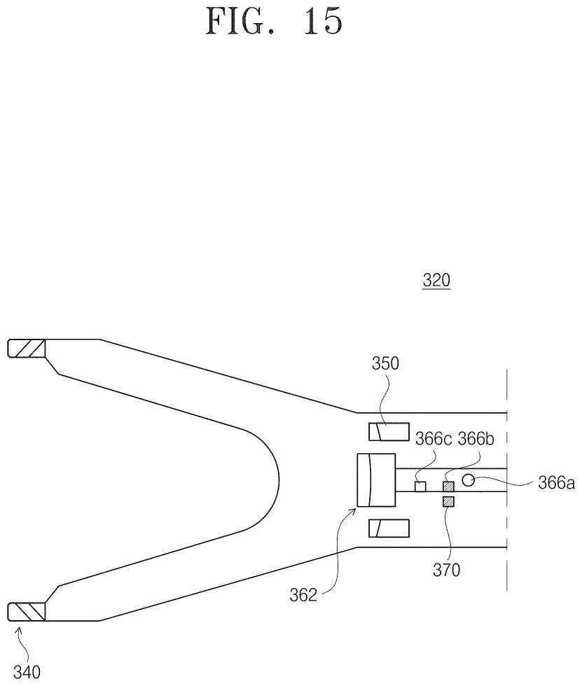

That is, while the relative position of the movable guide 362 with respect to the support plate 330 is changed from the first position P1 to the second position P2, the relative position between the movable guide unit 360 and the support plate 330 is changed by moving forward the support plate 330 coupled to the arm 314 and the arm 314 in a state in which the power applied to the electromagnet 316a is turned on so that the permanent magnet 370 may be switched from the state in which the permanent magnet 370 is magnetically coupled to the third magnetic block 366c to the state in which the permanent magnet 370 is magnetically coupled to the second magnetic block 366b. As illustrated in FIG. 15, when the permanent magnet 370 is magnetically coupled to the second magnetic block 366b so that the relative position between the movable guide unit 360 and the support plate 330 is in the second position P2, the power applied to the electromagnet 316a may be turned off.

As described above, when the process of changing the relative position of the movable guide 362 with respect to the support plate 330 from the first position P1 to the second position P2 is reversed, the relative position of the movable guide 362 with respect to the support plate 330 may be changed from the second position P2 to the first position P1. The switching of the movable guide 362 to the first position P1 may be performed in the above-described operation S12 of switching to the first position S12.

The first transfer robot 300, in which the movable guide 362 is switched to the second position P2, transfers the substrate W2 after processing (S34).

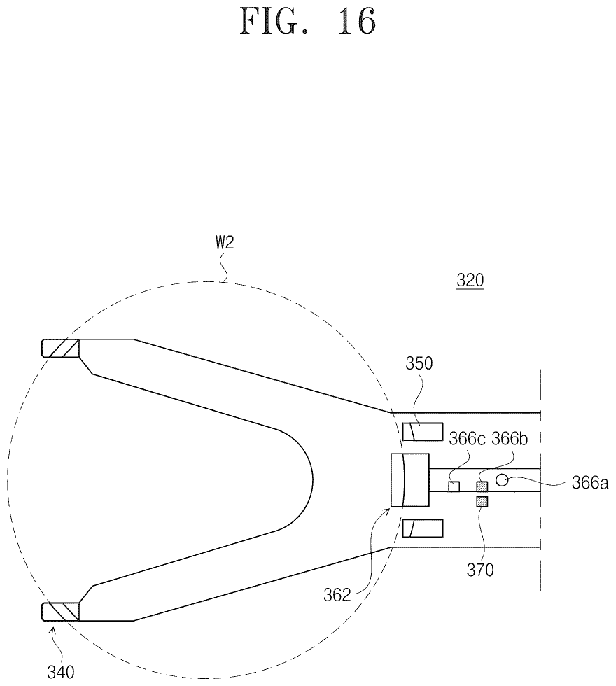

FIG. 16 is a diagram illustrating a process in which the hand of FIG. 3 transfers a substrate after processing. Referring to FIGS. 6 and 16, a substrate W2 after processing may be transferred to the index module 10 in a state of being seated on the second front support surface 346 and the movable support surface 362a (S34). The substrate W2 after processing may be transferred to the load port 120 by the first transfer robot 300.

The substrate processing method according to the above-described exemplary embodiment was described based on the case where the operations in which the substrate before processing is loaded into the chamber (S10), the substrate is processed in the chamber (S20), and the substrate after processing is unloaded from the chamber (S30) are performed in the process chamber 260, that is, the liquid treating chamber for liquid treating the substrate W, as an example.

However, unlike this, the process chamber 260 may be a drying chamber for drying the substrate W, or may further include a drying chamber in addition to the liquid treating chamber. The drying chamber may be a supercritical chamber for drying a substrate using a supercritical fluid.

According to the above-described exemplary embodiment, the first transfer robot 300 may be provided as an index robot to transfer the substrate W between the index module 10 and the treating module 20. In this case, a plurality of hands 320 provided to the first transfer robot 300 may transfer the substrate W1 before processing and the substrate W2 after processing by using different support surfaces at different heights h1 and h2.

The hand 320 of the present invention includes the front guide 340 capable of supporting the substrates W at different heights h1 and h2 on the support plate 330, the rear guide 350 capable of supporting the substrate W at the first height h1, the movable guide 362 capable of supporting the substrate W at the second height h2 while moving horizontally on the support plate 330, and the movable guide 362 may support the substrate W1 before processing and the substrate W2 after processing at different heights h1 and h2 by using different support surfaces by switching positions between the first position P1 and the second position P2 on the support plate 330.

Therefore, since the hand 320 of the present invention is provided to support the substrate W1 before processing and the substrate W2 after processing with different support surfaces, it is possible to prevent reverse contamination of the hand 320 and other substrates W through the substrate W. In other words, it is possible to prevent contaminants, such as particles or fumes, of the contaminated (dirty) substrate W1 before processing from contaminating the cleaned substrate W2 after processing during the process of transferring the substrate W through the hand 320 of the present invention.

In addition, since the substrate W1 before processing and the substrate W2 after processing may be supported and transferred with different support surfaces with one hand 320, both the substrate W1 before processing and the substrate W2 after processing may be transferred with the hand 320, thereby increasing the transfer efficiency of the substrate W. Compared to the case of transferring the substrate W1 before processing and the substrate W2 after processing through different hands, respectively, the configuration of the first transfer robot 300 may be simplified, the overall height of the hand 320 may be lowered, and the weight of the first transfer robot 300 may be reduced.

According to the above-described exemplary embodiment, the movable guide 362 moves relative to the arm 314 by the electromagnet 316a of the body 316 fixed to the base 310. In other words, since a separate driving device or power source directly connected to the movable guide 362 is not required to move the movable guide 362 while the movable guide 362 moves relative to the arm 314 and the support plate 330, it is not necessary to install a configuration, such as a driving device or a power cable for driving the driving device, on the hand 320 and thus the configuration of the hand 320 may be simplified.

In the above-described exemplary embodiment, it has been illustrated and described that the front guide 340 includes the first front supporting part supporting the substrate W at the first height h1 and the second front supporting part supporting the substrate W at the second height h2, but the front guide 340 has an integral body including the first front support surface 342 and the second front support surface 346. However, unlike this, the first front support part supporting the substrate W at the first height h1 and the second front support part supporting the substrate W at the second height h2 may have separate bodies and may be provided at the front ends of the first finger 334 and the second finger 336 of the support plate 330.

In the above exemplary embodiment, only the first transfer robot 300 is described, and a description of the second transfer robot 244 is omitted. However, the configuration of the above-described first transfer robot 300 may be equally applied to the second transfer robot 244.

For example, the second transfer robot 244 may transfer the substrate W1 before processing from the buffer chamber 220 to the process chamber 260 and transfer the substrate W2 from the process chamber 260 to the buffer chamber 220, and transfer the substrate W1 before processing and the substrate W2 after processing in a state of being supported using different support surfaces at different heights h1 and h2.

For example, the second transfer robot 244 may include a plurality of arms 314 to which one hand 320 is coupled. Even in this case, it is a matter of course that each arm 314 may be driven simultaneously or independently.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. A transfer robot for transferring a substrate, the transfer robot comprising:
a base;
an arm which is connected to the base and is movable forward and backward with respect to the base;
a hand connected to the arm;
a driving unit for driving the arm; and
a body which includes an electromagnet and is fixedly installed on the base,
wherein the hand includes:
a support plate;
a front guide fixedly installed at a front end of an upper surface of the support plate to support a region of a lower surface of an edge of a substrate placed on the support plate;
a rear guide fixedly installed at a rear side of the upper surface of the support plate and including a rear support surface for supporting the region of the lower surface of the edge of the substrate placed on the support plate; and
a movable guide unit located at the rear side of the upper surface of the support plate and movable between a first position at which the substrate is not supported and a second position capable of supporting the region of the lower surface of the substrate,
the movable guide unit includes:
a rail;
a movable guide including a movable support surface capable of supporting the region of the lower surface of the substrate, and movable along the rail;
a support rod connected to the movable guide; and
a first magnetic block fixedly installed on the support rod and connectable with the electromagnet by magnetic force.

2. The transfer robot of claim 1, wherein the front guide includes:
a first front support part for supporting the substrate at a first height; and
a second front support part for supporting the substrate at a second height different from the first height,
the rear guide is provided to support the substrate at the first height, and
the movable guide is provided to support the substrate at the second height when the movable guide is in the second position.

3. The transfer robot of claim 1, wherein the hand further includes a permanent magnet fixedly installed on an upper portion of the support plate,
the movable guide unit further includes a second magnetic block and a third magnetic block fixedly installed on the support rod,
the second magnetic block is magnetically coupled to the permanent magnet when the movable guide unit is in the first position to fix a position of the movable guide unit with respect to the support plate, and
the third magnetic block is magnetically coupled to the permanent magnet when the movable guide unit is in the second position to fix the position of the movable guide unit with respect to the support plate.

4. The transfer robot of claim 3, wherein the front guide, the rear guide, the third magnetic block, the second magnetic block, and the first magnetic block are sequentially arranged in one direction.

5. The transfer robot of claim 2, wherein each of the first front support part, the second front support part, the rear support surface, and the movable support surface is formed with a support protrusion supporting the lower surface of the substrate.

6. The transfer robot of claim 2, wherein when the movable guide is in the first position, the substrate is supported by the first front support part and the rear support surface, and
when the movable guide is in the second position, the substrate is supported by the second front support part and the movable support surface.

7. The transfer robot of claim 6, wherein when viewed from above, a center position of the substrate when the first front support part and the rear support surface support the substrate at the first height and a center position of the substrate when the second front support part and the movable support surface support the substrate at the second height are different from each other.

8. The transfer robot of claim 6, wherein the movable guide further includes a movable guide surface that guides a lateral surface of the substrate supported by the first front support part and the rear support surface when the movable guide is in the first position.

9. The transfer robot of claim 1, wherein the support plate includes:
a connection part coupled to the arm; and
a first finger and a second finger extending from the connection part, and
the front guide is provided to each of front ends of the first finger and the second finger, and
the connection part is provided with the rear guide and the movable guide.

10. The transfer robot of claim 2, wherein the front guide is provided as an integrated body including a first front support surface provided as the first front support part and a second front support surface provided as the second front support part.

11. The transfer robot of claim 1, wherein a plurality of arms is provided, and each of the plurality of arms is provided with one or more hands coupled to be spaced apart in a vertical direction.

12. The transfer robot of claim 2, further comprising:
a controller,
wherein the controller changes a relative position of the movable guide unit with respect to the support plate by controlling the first magnetic block to be selectively coupled with the electromagnet by turning on/off a power applied to the electromagnet.

13. The transfer robot of claim 12, wherein when the hand supports a substrate before processing, the controller switches a position of the movable guide to the first position to control the front guide and the rear guide to support the substrate before processing at the first height, and
when the hand supports a substrate after processing, the controller switches the position of the movable guide to the second position to control the front guide and the movable guide to support the substrate after processing at the second height.

14. An apparatus for processing a substrate, the apparatus comprising:
an index module including a load port for loading and unloading a substrate;
a treating module including a process chamber for processing a substrate;
a controller; and
the transfer robot of claim 1 for transferring the substrate between the index module and the treating module,
wherein the hand further includes a permanent magnet fixedly installed on an upper portion of the support plate,
the movable guide unit further includes a second magnetic block and a third magnetic block fixedly installed on the support rod,
the second magnetic block is magnetically coupled to the permanent magnet when the movable guide unit is in the first position to fix a position of the movable guide unit with respect to the support plate,
the third magnetic block is magnetically coupled to the permanent magnet when the movable guide unit is in the second position to fix a position of the movable guide unit with respect to the support plate,
the front guide includes:
a first front support part for supporting the substrate at a first height; and
a second front support part for supporting the substrate at a second height different from the first height,
the rear guide is provided to support the substrate at the first height, and
the movable guide is provided to support the substrate at the second height when the movable guide is in the second position, and
when the hand transfers a first substrate and a second substrate, the controller changes a relative position of the movable guide with respect to the support plate to transfer the substrates in a state where the hand supports the respective substrates at different heights.

15. The apparatus of claim 14, wherein the controller changes the relative position of the movable guide unit with respect to the support plate by controlling the first magnetic block to be selectively coupled with the electromagnet by turning on/off a power applied to the electromagnet.

16. The apparatus of claim 14, wherein
the first substrate is a substrate before processing that has not been processed in the process chamber, and
the second substrate is a substrate after processing that has been processed in the process chamber, and
when the hand transfers the substrate before processing, the controller switches a position of the movable guide to the first position to control the front guide and the rear guide to support the substrate before processing at the first height, and
when the hand transfers the substrate after processing, the controller switches the position of the movable guide to the second position to control the front guide and the movable guide to support the substrate after processing at the second height.

17. The apparatus of claim 16, wherein when viewed from above, a center position of the substrate when the first front support part and the rear support surface support the substrate before processing at the first height and a center position of the substrate when the second front support part and the movable support surface support the substrate after processing at the second height are different from each other.

18. A transfer robot for transferring a substrate, the transfer robot comprising:
a base;
an arm which is connected to the base and is movable forward and backward with respect to the base;
a hand connected to the arm;
a driving unit for driving the arm; and
a body which includes an electromagnet and is fixedly installed on the base,
wherein the hand includes:
a support plate;
a front guide fixedly installed at a front end of an upper surface of the support plate to support a region of a lower surface of an edge of a substrate placed on the support plate;
a rear guide fixedly installed at a rear side of the upper surface of the support plate and including a rear support surface for supporting the region of the lower surface of the edge of the substrate placed on the support plate;
a movable guide unit located at a rear side of the upper surface of the support plate and movable between a first position at which the substrate is not supported and a second position capable of supporting the region of the lower surface of the substrate; and
a permanent magnet fixedly installed on an upper portion of the support plate,
the front guide includes:
a first front support surface for supporting the substrate at a first height; and
a second front support surface for supporting the substrate at a second height different from the first height,
the movable guide unit includes:
a rail;
a movable guide including a movable support surface capable of supporting the region of the lower surface of the substrate, and movable along the rail;
a support rod connected to the movable guide;
a first magnetic block installed on the support rod and connectable with the electromagnet by magnetic force; and
a second magnetic block and a third magnetic block fixedly installed on the support rod,
the second magnetic block is magnetically coupled to the permanent magnet when the movable guide unit is in the first position to fix a position of the movable guide unit with respect to the support plate,
the third magnetic block is magnetically coupled to the permanent magnet when the movable guide unit is in the second position to fix a position of the movable guide unit with respect to the support plate,
the rear guide is provided to support the substrate at the first height, and
the movable guide is provided to support the substrate at the second height when the movable guide is in the second position.

19. The transfer robot of claim 18, wherein when the movable guide is in the first position, the substrate is supported by the first front support surface and the rear support surface, and
when the movable guide is in the second position, the substrate is supported by the second front support surface and the movable support surface, and
a center position of the substrate when the first front support surface and the rear support surface support the substrate at the first height and a center position of the substrate when the second front support surface and the movable support surface support the substrate at the second height are different from each other.

20. The transfer robot of claim 18, further comprising:
a controller,
the controller changes a relative position of the movable guide unit with respect to the support plate by controlling the first magnetic block to be selectively coupled with the electromagnet by turning on/off a power applied to the electromagnet, and
when the hand supports a substrate before processing, the controller switches a position of the movable guide to the first position to control the front guide and the rear guide to support the substrate before processing at the first height, and
when the hand supports a substrate after processing, the controller switches the position of the movable guide to the second position to control the front guide and the movable guide to support the substrate after processing at the second height.
